(19) United States
(12) Patent Application Publication
(10) Pub. No.: US 2024/0090333 A1
(43) Pub. Date: Mar. 14, 2024

(54) METHOD FOR MANUFACTURING PIEZOELECTRIC TRANSDUCER

(71) Applicant: SPECTRON (SHENZHEN) TECHNOLOGIES CO., LTD, Shenzhen (CN)

(72) Inventors: Songbin GONG, Shenzhen (CN); Yansong YANG, Shenzhen (CN)

(21) Appl. No.: 18/275,458

(22) PCT Filed: May 31, 2021
(86) PCT No.: PCT/CN2021/097219

§ 371 Date: Aug. 2, 2023

(30) Foreign Application Priority Data
Apr. 8, 2021 (CN) 202110376688.3

(51) Int. Cl. H10N 30/80; G03F 7/00; G03F 7/40; H10N 30/072

(52) U.S. Cl. CPC H10N 30/80; G03F 7/0035; G03F 7/40; H10N 30/072

(57) ABSTRACT

A method for manufacturing a piezoelectric transducer, comprising: forming, on a piezoelectric wafer, a first mark parallel to or perpendicular to a preset direction of the piezoelectric transducer; forming, on a carrier wafer, a second mark parallel to or perpendicular to a cutting direction of the carrier wafer, the shape of the second mark being the same as that of the first mark; and aligning the first mark and the second mark, and then bonding the piezoelectric wafer and the carrier wafer to form a process wafer, a first surface of the process wafer where the piezoelectric wafer is provided being used for forming the piezoelectric transducer. The preset direction of the piezoelectric transducer is made to be parallel to or perpendicular to the cutting direction of the carrier wafer by means of the first mark on the piezoelectric wafer and the second mark on the carrier wafer.

### TECHNICAL FIELD

The present disclosure relates to the field of semiconductor technology, in particular to a method for preparing a piezoelectric transducer.

### BACKGROUND

Crystal orientations of a piezoelectric film for preparing a piezoelectric transducer in a vertical direction of a carrier wafer and a plane direction parallel to the carrier wafer is dictated by the deposition process, and the crystal orientations of the piezoelectric film in the vertical direction of the carrier wafer and in the plane direction parallel to the carrier wafer cannot be arbitrarily controlled without significant modifications of the deposition process.

However, after the piezoelectric wafer with different crystal orientations in the vertical direction of the carrier wafer is bonded to the carrier wafer, and the piezoelectric wafer is thinned to a thickness required for the preparation of the piezoelectric transducer, the piezoelectric film used for preparing the piezoelectric transducer can have different crystal orientations. The piezoelectric transducer has certain flexibility in the orientations. However, in order to obtain the piezoelectric transducer with optimal performance, it is necessary to place the piezoelectric transducer in different directions on the piezoelectric wafer as needed. When the direction is not parallel or perpendicular to the dicing direction of the carrier wafer, it will result in inefficient use of the available wafer area of the piezoelectric wafer.

### SUMMARY

Accordingly, it is necessary to provide a new method for preparing the piezoelectric transducer to address the problem of inefficient use of the available wafer area of the piezoelectric wafer in the related art.

In order to achieve the above object, the present disclosure provides a method of preparing piezoelectric transducer, including: forming a first marker parallel to or perpendicular to a preset direction of the piezoelectric transducer on a piezoelectric wafer; forming a second marker parallel to or perpendicular to a dicing direction of a carrier wafer on the carrier wafer, the second marker and the first marker having the same shape; and aligning the first marker and the second mark, bonding the piezoelectric wafer and the carrier wafer to form a process wafer. The process wafer includes a first surface of the piezoelectric wafer configured to form the piezoelectric transducer.

In one of the embodiments, the first marker includes a first primary positioning edge of the piezoelectric wafer, the second marker includes a second primary positioning edge of the carrier wafer. The step of forming the first marker parallel to or perpendicular to the preset direction of the piezoelectric transducer on the piezoelectric wafer includes: grinding or cutting the piezoelectric wafer along a first direction to form the first primary positioning edge, the first direction being parallel or perpendicular to the preset direction. The step of forming the second marker parallel to or perpendicular to the dicing direction of the carrier wafer on the carrier wafer includes: grinding or cutting the carrier wafer along a second direction to form the second primary positioning edge, the second direction being parallel or perpendicular to the dicing direction.

In one of the embodiments, a first preset angle is formed between the preset direction and a crystal axis direction of the piezoelectric wafer, and a second preset angle is formed between the dicing direction and a crystal axis direction of the carrier wafer.

In one of the embodiments, the first preset angle is an angle by which the preset direction rotates counterclockwise to the crystal axis direction of the piezoelectric wafer, and the second preset angle is the angle by which the dicing direction rotates counterclockwise to the crystal axis direction of the carrier wafer.

In one of the embodiments, the first preset angle is the angle by which the preset direction rotates clockwise to the crystal axis direction of the piezoelectric wafer, and the second preset angle is the angle by which the dicing direction rotates clockwise to the crystal axis direction of the carrier wafer.

In one of the embodiments, the first preset angle includes 0 degrees and 90 degrees, and/or the second preset angle includes 0 degrees and 90 degrees.

In one of the embodiments, the piezoelectric wafer further includes a first secondary positioning edge perpendicular to the first primary positioning edge, and the carrier wafer further includes a second secondary positioning edge perpendicular to the second primary positioning edge.

In one of the embodiments, the first marker includes a first marking pattern provided on the piezoelectric wafer, and the second marker includes a second marking pattern provided on the carrier wafer. The step of forming the first marker parallel to or perpendicular to the preset direction of the piezoelectric transducer on the piezoelectric wafer includes: forming a first marking pattern on the piezoelectric wafer by a photolithography and etching process, a direction of the first marking pattern being parallel or perpendicular to the preset direction. The step of forming the second marker parallel to or perpendicular to the dicing direction of the carrier wafer on the carrier wafer includes: forming a second marking pattern on the carrier wafer by a photolithography and etching process, and a direction of the second marking pattern being parallel to or perpendicular to the dicing direction.

In one of the embodiments, the step of forming the first marking pattern on the piezoelectric wafer by the photolithography and etching process includes: forming a first marking film layer on the piezoelectric wafer, and performing the photolithography and etching process to the first marking film layer, and obtaining the first marking pattern. The step of forming the second marking pattern on the carrier wafer by the photolithography and etching process includes: forming a second marking film layer on the carrier wafer, performing the photolithography and etching process to the second marking film layer, and obtaining the second marking pattern. The first marking film layer and the second marking film layer include at least a silicon dioxide film layer.

In one of the embodiments, the first marking pattern is formed by the first marking film layer, and the second marking pattern is a groove provided in the second marking film layer. Alternatively, the first marking pattern is a groove provided in the first marking film layer, and the second marking pattern is formed by the second marking film layer.

According to the above-mentioned method of preparing piezoelectric transducer, firstly, the first marker parallel to or perpendicular to the preset direction of the piezoelectric transducer is formed on the piezoelectric wafer, the second marker parallel to or perpendicular to the dicing direction of the carrier wafer is formed on the carrier wafer, and the shape of the second marker and the shape of the first marker are the same, and then, the first marker and the second marker are aligned, the piezoelectric wafer and the carrier wafer are bonded to obtain the process wafer to form the piezoelectric transducer. This application uses the first marker on the piezoelectric wafer and the second marker on the carrier wafer to enable the preset direction of the piezoelectric transducer to be parallel or perpendicular to the dicing direction of the carrier wafer, so as to achieve the object of improving the utilization of the available wafer area of the carrier wafer.

### BRIEF DESCRIPTION OF THE DRAWINGS

To illustrate the technical solutions according to the embodiments of the present disclosure or in the prior art more clearly, the accompanying drawings for describing the embodiments or the prior art are introduced briefly in the following. Apparently, the accompanying drawings in the following description are only some embodiments of the present invention, and persons of ordinary skill in the art can derive other drawings from the accompanying drawings without creative efforts.

FIG. 1 is a flowchart of a method for preparing a piezoelectric transducer according to an embodiment.

FIG. 2 is a top view of a piezoelectric wafer according to an embodiment.

FIG. 3 is a top view of a carrier wafer according to an embodiment.

FIG. 4 is a top view illustrating an alignment process of a first primary positioning edge of the piezoelectric wafer shown in FIG. 2 and a second primary positioning edge of the carrier wafer shown in FIG. 3 according to an embodiment.

FIG. 5 is a flowchart of forming a first marking pattern on a piezoelectric wafer according to an embodiment.

FIG. 6 is a flowchart of forming a second marking pattern on a carrier wafer according to an embodiment.

FIG. 7 is a top view of a piezoelectric wafer according to another embodiment.

FIG. 8 is a top view of a carrier wafer according to another embodiment.

FIG. 9 is a top view illustrating an alignment process of a first marking pattern on the piezoelectric wafer shown in FIG. 7 and a second marking pattern on the carrier wafer shown in FIG. 8 according to an embodiment.

### DETAILED DESCRIPTION OF THE EMBODIMENTS

In order to facilitate the understanding of the present application, the present application will be described more fully below with reference to the relevant drawings. Embodiments of the application are given in the drawings. However, the present application can be implemented in many different forms and is not limited to the embodiments described herein. Conversely, the purpose of providing these embodiments is to make the disclosure of this application more thorough and comprehensive.

Unless otherwise defined, all technical and scientific terms used herein have the same meaning as commonly understood by one of ordinary skill in the technical field to which this application belongs. The terms used herein in the specification of the application are only for the purpose of describing specific embodiments, and are not intended to limit the application.

It should be understood that when an element or layer is referred to as being “on”, “adjacent to”, “connected to” or “coupled to” another element or layer, it may be directly on, adjacent to, connected or coupled to the another element or layer, or there may be intermediate elements or layers. Conversely, when an element is referred to as being “directly on”, “directly adjacent to”, “directly connected to”, or “directly coupled to” another element or layer, there are no intermediate element or layer. It should be understood that although the terms first, second, third, etc. may be used to describe various elements, components, regions, layers, doping types and/or portions, these elements, components, regions, layers, doping types and/or portions should not be limited by these terms. These terms are only used to distinguish an element, component, region, layer, doping type or portion from another element, component, region, layer, doping type or portion. Thus, a first element, component, region, layer or portion discussed below could be termed a second element, component, region, layer or portion without departing from the teachings of the present disclosure. For example, the first doping type may be a second doping type, and similarly, the second doping type may be a first doping type. The first doping type and the second doping type are different doping types, for example, the first doping type may be P-type and the second doping type may be N-type, or the first doping type may be N-type and the second doping type may be P-type.

Spatial relationship terms such as “below”, “under”, “on”, “above”, etc., may be used herein to describe the relationship between an element or feature shown in the diagram and other components or features and other elements or features shown in the figures. It should be understood that in addition to the orientations shown in the figures, the spatial relationship terms include different orientations of the devices in use and operation. For example, if a device in the figures is turned over, elements or features described as “below” or “under” other elements or features would then be oriented “above” the other elements or features. Thus, the exemplary terms “below” and “under” can include both an orientation of above and below. In addition, the device may be otherwise oriented (e.g., rotated 90 degrees or at other orientations) and the spatial descriptors used herein interpreted accordingly.

When used herein, the singular forms “a”, “an” and “the” may also include the plural forms unless the context clearly dictates otherwise. It should also be understood that the terms “comprising/including” or “having”, etc. specify the presence of stated features, integers, steps, operations, components, portions or combinations thereof, but do not exclude the presence or addition of one or more other features, integers, steps, operations, components, portions or combinations thereof. Meanwhile, in this specification, the term “and/or” includes any and all combinations of the related listed items.

Embodiments of the present disclosure are described herein with reference to cross-section illustrations that are schematic illustrations of idealized embodiments (and intermediate structures) of the present disclosure, such that variations in the shapes shown as a result, for example, of manufacturing techniques and/or tolerances are contemplated. Thus, embodiments of the present disclosure should not be limited to the particular shapes of regions shown herein but are to include deviations in shapes that result, for example, from manufacturing techniques. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation was performed. Thus, the regions shown in the figures are substantially schematic and their shapes do not indicate the actual shape of a region of a device and are not intended to limit the scope of the present disclosure.

A typical way of preparing piezoelectric transducers using thin-film transfer technology, although it is possible to integrate piezoelectric wafers with different crystallographic orientations in a direction perpendicular to a substrate plane of the carrier wafer as a piezoelectric film layer depending on productivity and commercial availability, so as to solve the problem that crystal orientations of a piezoelectric film in a vertical direction of the carrier wafer and in a plane direction parallel to the carrier wafer cannot be arbitrarily controlled without significantly changing the deposition process. However, a primary positioning edge or a secondary positioning edge of the standard wafer is parallel or perpendicular to a main crystal axis of a wafer material, and a dicing direction of the wafer is parallel or perpendicular to the primary positioning edge or the secondary positioning edge, the piezoelectric wafer on the carrier wafer is equivalent to a thin film formed on the piezoelectric wafer. Therefore, the dicing direction of the wafer after bonding is dictated by the dicing direction of the carrier wafer. The best performance of the piezoelectric transducer is determined by the orientation in the plane of the carrier wafer after the bonding. When the orientation is not parallel or perpendicular to the primary positioning edge (dicing direction) of the carrying wafer, the direction of the piezoelectric transducer intersects the dicing direction, which will cause dicing the piezoelectric transducer on the on the carrier wafer into smaller chips becomes impossible and the use of an available wafer area of the carrier wafer becomes inefficient.

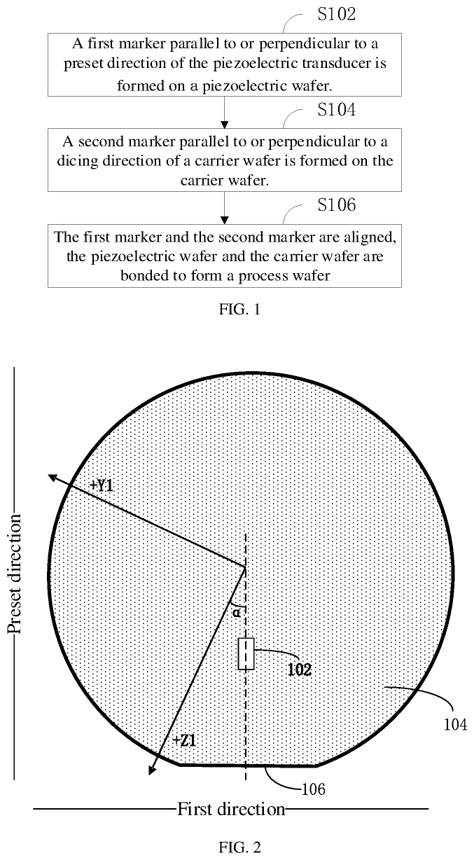

Referring to FIG. 1, it is a flowchart of a method for preparing a piezoelectric transducer according to an embodiment.

In order to solve the above problem, in one of the embodiments, a method for preparing a piezoelectric transducer is provided. As shown in FIG. 1, the method includes:

S102, a first marker parallel to or perpendicular to a preset direction of the piezoelectric transducer is formed on a piezoelectric wafer.

The piezoelectric wafer having preset crystal orientations in the vertical direction of the wafer and in the direction parallel to a wafer plane is acquired, and then the first marker parallel to or perpendicular to the preset direction of the piezoelectric transducer is formed on the piezoelectric wafer. The preset direction refers to a device direction of the subsequently formed piezoelectric transducer.

In one of the embodiments, the piezoelectric wafer includes at least one of a lithium niobate wafer, a lithium tantalate wafer, an aluminum nitride wafer, and a quartz wafer.

S104, a second marker parallel to or perpendicular to a dicing direction of a carrier wafer is formed on the carrier wafer.

The carrier wafer is acquired, and then the second marker parallel or perpendicular to the dicing direction of the carrier wafer is formed on the carrier wafer. The second marker and the first marker have the same shape. The dicing direction of the carrier wafer refers to the direction in which the carrier wafer is diced or cut.

In one of the embodiments, the carrier wafer includes at least one of a silicon wafer, a sapphire wafer, a silicon carbide wafer, a quartz wafer, a glass wafer, and a piezoelectric material wafer.

S106, after the first marker and the second marker are aligned, the piezoelectric wafer and the carrier wafer are bonded to form a process wafer.

After aligning the first marker on the piezoelectric wafer with the second marker on the carrier wafer, the piezoelectric wafer and the carrier wafer are bonded together through a bonding process to form the process wafer. The process wafer includes a first surface of the piezoelectric wafer and configured to form the piezoelectric transducer.

According to the above-mentioned method of preparing piezoelectric transducer, firstly, the first marker parallel to or perpendicular to the preset direction of the piezoelectric transducer is formed on the piezoelectric wafer, the second marker parallel to or perpendicular to the dicing direction of the carrier wafer is formed on the carrier wafer, and the shape of the second marker and the first marker are the same, and then, the first marker and the second marker are aligned, the piezoelectric wafer and the carrier wafer are bonded to obtain the process wafer to form the piezoelectric transducer. This application uses the first marker on the piezoelectric wafer and the second marker on the carrier wafer to enable the preset direction of the piezoelectric transducer to be parallel or perpendicular to the dicing direction of the carrier wafer, so as to achieve the purpose of improving the utilization of the available wafer area of the carrier wafer.

In one of the embodiments, the first marker includes a first primary positioning edge of the piezoelectric wafer, and the second marker includes a second primary positioning edge of the carrier wafer. Step S102 includes:

The piezoelectric wafer is ground or cut along a first direction to form the first primary positioning edge. The first direction is parallel to or perpendicular to the preset direction, that is, the direction of the first primary positioning edge of the piezoelectric wafer is parallel or perpendicular to the preset direction of the piezoelectric transducer.

Step S104 includes:

The carrier wafer is ground or cut along a second direction to form the second primary positioning edge. The second direction is parallel or perpendicular to the dicing direction, that is, the direction of the first primary positioning edge of the carrier wafer is parallel or perpendicular to the dicing direction of the carrier wafer. At this time, after aligning the first primary positioning edge and the second primary positioning edge and bonding the piezoelectric wafer and the carrier wafer to obtain the process wafer, the device direction of the piezoelectric transducer formed on a first plane of the process wafer having the piezoelectric wafer is parallel or perpendicular to the dicing direction of the carrier wafer, so as to improve the utilization rate of the available wafer area of the carrier wafer.

In one of the embodiments, a first preset angle is formed between the preset direction and a crystal axis direction of the piezoelectric wafer, and a second preset angle is formed between the dicing direction and a crystal axis direction of the carrier wafer. The crystal axis direction refers to any crystal orientation of a crystal material constituting the wafer located in the wafer plane.

In one of the embodiments, there are crystal orientations A and B on the wafer plane of the piezoelectric wafer, and there are crystal orientations A and C on the wafer plane of the carrier wafer. The crystal axis direction of the piezoelectric wafer and the crystal axis direction of the carrier wafer are both in the direction of the crystal orientation A. Alternatively, the direction of the crystal axis of the piezoelectric wafer is in the direction of the crystal orientation B, and the direction of the crystal axis of the carrier wafer is in the direction of the crystal orientation C.

In one of the embodiments, the first preset angle is an angle by which the preset direction rotates counterclockwise to the crystal axis direction of the piezoelectric wafer, and the second preset angle is the angle by which the dicing direction rotates counterclockwise to the crystal axis direction of the carrier wafer.

In one of the embodiments, the first preset angle is the angle by which the preset direction rotates clockwise to the crystal axis direction of the piezoelectric wafer, and the second preset angle is the angle by which the dicing direction rotates clockwise to the crystal axis direction of the carrier wafer.

In one of the embodiments, the first preset angle includes 0 degrees and 90 degrees, and/or the second preset angle includes 0 degrees and 90 degrees.

In one of the embodiments, the dicing direction of the carrier wafer includes a first dicing direction and a second dicing direction that are orthogonal to each other.

In one of the embodiments, the piezoelectric wafer further includes a first secondary positioning edge perpendicular to the first primary positioning edge, and the carrier wafer further includes a second secondary positioning edge perpendicular to the second primary positioning edge. By providing the first secondary positioning edge and the second secondary positioning edge, the purpose of bonding a preset surface of the piezoelectric wafer to a preset surface of the carrier wafer can be achieved. When the first marker is the first primary positioning edge and the second marker is the second primary positioning edge, the first secondary positioning edge and the second secondary positioning edge serve the purpose of further aligning the piezoelectric wafer with the carrier wafer during the bonding process.

In one of the embodiments, the piezoelectric transducer is rectangular, and the direction of the piezoelectric transducer is oriented along the direction of a long side thereof.

In one of the embodiments, after aligning the first marker and the second mark, the step of bonding the piezoelectric wafer and the carrier wafer includes: forming a bonding auxiliary layer, aligning the first marker and the second mark, and bonding the piezoelectric wafer and the carrier wafer together through the bonding auxiliary layer to form the process wafer. The problem that some piezoelectric wafers and carrier wafers are not easy to be directly bonded is solved by providing the bonding auxiliary layer.

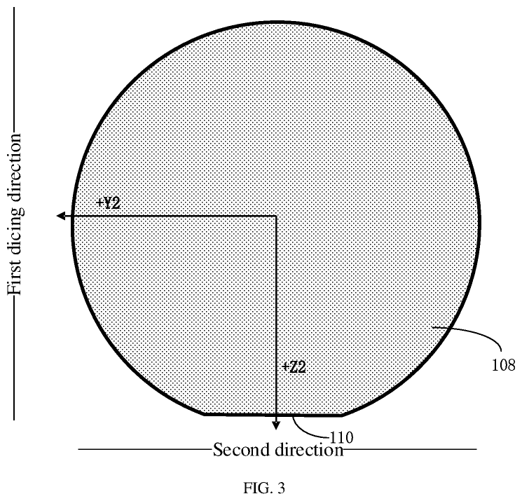

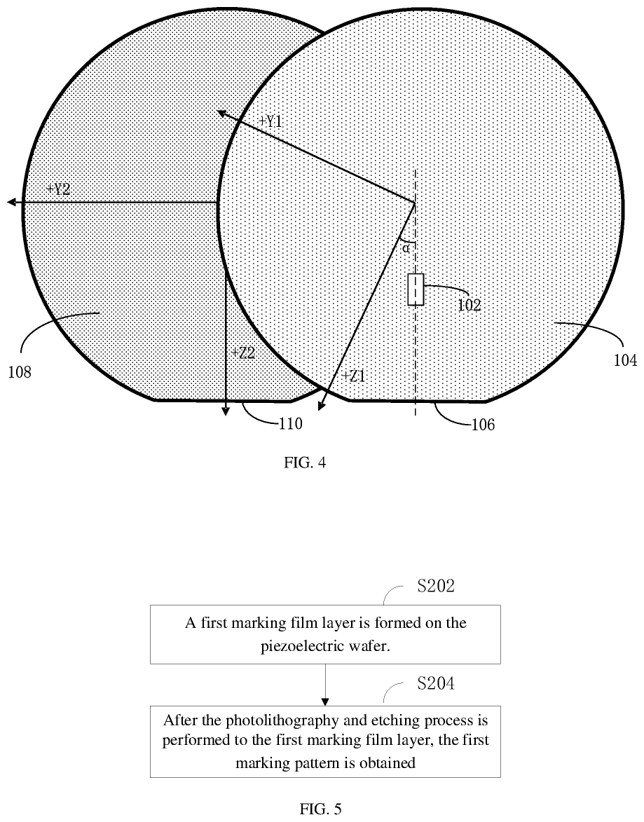

Referring to FIG. 2, it is a top view of the piezoelectric wafer according to an embodiment. Referring to FIG. 3, it is a top view of the carrier wafer according to an embodiment. Referring to FIG. 4, it is a top view illustrating an aligning process of the first primary positioning edge of the piezoelectric wafer shown in FIG. 2 with the second primary positioning edge of the carrier wafer shown in FIG. 3 according to an embodiment.

As shown in FIG. 2, FIG. 3, and FIG. 4, the method of preparing the piezoelectric transducer will be described in detail taking the first marker as the first primary positioning edge of the piezoelectric wafer, and the second marking as the second primary positioning edge of the carrier wafer, the first preset angle is greater than 0 degrees and less than 90 degrees, the second preset angle is 0 degrees or 90 degrees, and the first dicing direction is the dicing direction. In a first step, the piezoelectric wafer 104 is ground or cut along a first direction perpendicular to the preset direction of the piezoelectric transducer 102 to form the first primary positioning edge 106. The carrier wafer 108 is ground or cut in a second direction perpendicular to the first dicing direction to form the second primary positioning edge 110. There are crystal orientations+Y1 and crystal orientation+Z1 on the wafer plane of the piezoelectric wafer, and there are crystal orientations+Y2 and crystal orientation+Z2 on the wafer plane of the carrier wafer. The crystal orientation+Z1 is used as the crystal axis direction of the piezoelectric wafer, and the crystal orientation+Z2 is used as the crystal axis direction of the carrier wafer. The first preset angle formed between the preset direction and the crystal axis direction+Z1 of the piezoelectric wafer is a degree, a second preset angle formed between the first dicing direction and the crystal axis direction+Z2 of the carrier wafer is 0 degree. In a second step, the first primary positioning edge 106 is aligned with the second primary positioning edge 110, and then the bonding process is performed, and the piezoelectric wafer and the carrier wafer are bonded together to obtain a process wafer. At this time, the preset direction of the piezoelectric transducer is parallel to the first dicing direction of the carrier wafer.

In one of the embodiments, the first marker includes a first marking pattern provided on the piezoelectric wafer, and the second marker includes a second marking pattern provided on the carrier wafer. Step S102 includes:

The first marking pattern is formed on the piezoelectric wafer by a photolithography and etching process, a direction of the first marking pattern is parallel or perpendicular to the preset direction.

Step S104 includes:

The second marking pattern is formed on the carrier wafer by a photolithography and etching process, and a direction of the second marking pattern is parallel to or perpendicular to the dicing direction.

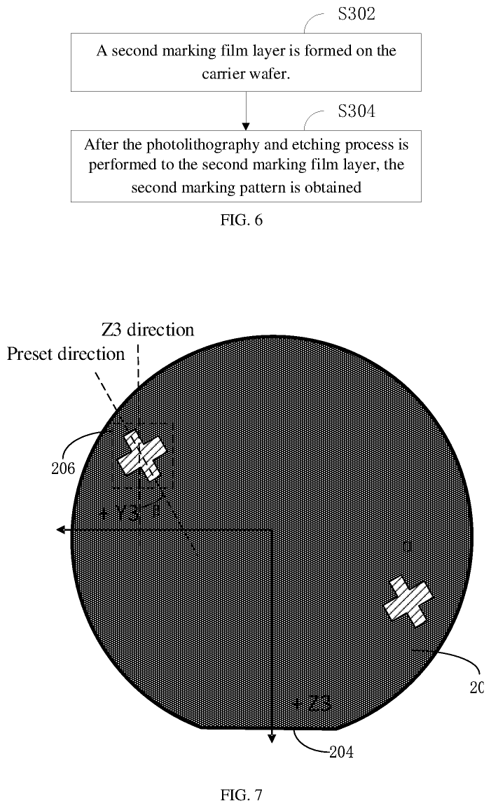

Referring to FIG. 5, it is a flowchart of forming the first marking pattern on the piezoelectric wafer according to an embodiment. Referring to FIG. 6, it is a flowchart of forming the second marking pattern on the carrier wafer according to an embodiment.

As shown in FIG. 5 and FIG. 6, in one of the embodiments, the step of forming the first marking pattern on the piezoelectric wafer by the photolithography and etching process includes:

S202, a first marking film layer is formed on the piezoelectric wafer.

The first marking film layer for forming a first marking pattern is formed on the piezoelectric wafer by using a film forming process well known in the art.

S204, after the photolithography and etching process is performed to the first marking film layer, the first marking pattern is obtained.

Using a photoresist plate corresponding to the first marking pattern to expose and develop the first marking film layer, and then the first marking film layer that is not covered by photoresist is etched and removed to obtain the first marking pattern.

The step of forming the second marking pattern on the carrier wafer by the photolithography and etching process includes:

S302, a second marking film layer is formed on the carrier wafer.

The second marking film layer for forming a second marking pattern is formed on the carrier wafer by using a film forming process well known in the art. The first marking film layer and the second marking film layer include at least a silicon dioxide film layer.

In one of the embodiments, the first marking film layer and the second marking film layer are film layers made of the same material.

S304, after the photolithography and etching process is performed to the second marking film layer, the second marking pattern is obtained.

Using a photoresist plate corresponding to the second marking pattern to expose and develop the second marking film layer, and then the second marking film layer that is not covered by photoresist is etched and removed to obtain the second marking pattern.

In one of the embodiments, the first marking pattern is formed by the first marking film layer, and the second marking pattern is a groove provided in the second marking film layer.

Alternatively, the first marking pattern is a groove provided in the first marking film layer, and the second marking pattern is formed by the second marking film layer.

Specifically, the first marking pattern is a convex mark on the piezoelectric wafer, the second marking pattern is a concave mark on the carrier wafer, or the first marking pattern is a concave mark on the piezoelectric wafer, and the second marking pattern is a convex mark on the carrier wafer. When the first marker is aligned with the second mark, the first marking pattern and the second marking pattern are embedded together.

In one of the embodiments, the first marking pattern is obtained by performing a direct photolithography and etching process to the piezoelectric wafer, and the second marking pattern is obtained by performing a direct photolithography and etching process to the carrier wafer.

In one of the embodiments, the first marker pattern and second marker pattern are both cross-shaped patterns. In other embodiments, the shapes of the first marking pattern and the second marking pattern can be selected as required.

In one of the embodiments, the number of the first marking pattern and the second marking pattern is not less than one.

In one of the embodiments, the first marking patterns M1 and M2 on the piezoelectric wafer are located at two opposite corners of a surface of the piezoelectric wafer, respectively. The second marking patterns N1 and N2 are respectively located at two opposite corners of a surface of the carrier wafer.

In one of the embodiments, the method of preparing piezoelectric transducer further includes:

After the piezoelectric wafer on the first surface is thinned to a preset thickness, the first surface of the process wafer having the piezoelectric wafer is patterned by a semiconductor-based manufacturing process, and the piezoelectric transducer is formed on the first surface.

The piezoelectric transducer includes a piezoelectric transducer having a Manhattan geometry, and a piezoelectric transducer formed by interdigitated electrodes parallel or orthogonal to the second primary positioning edge of the carrier wafer or the dicing direction. The preset thickness refers to a thickness of the thinned piezoelectric wafer (i.e., the required piezoelectric film) when forming the piezoelectric transducer.

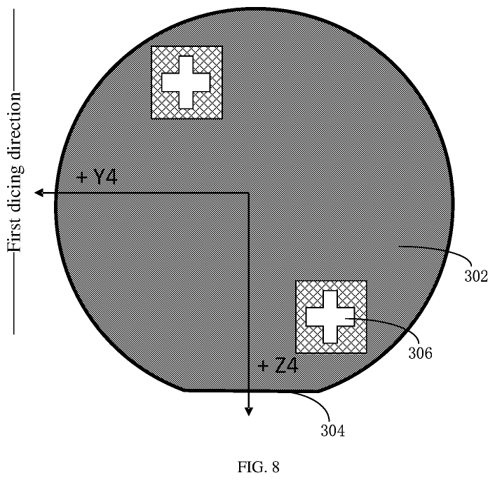

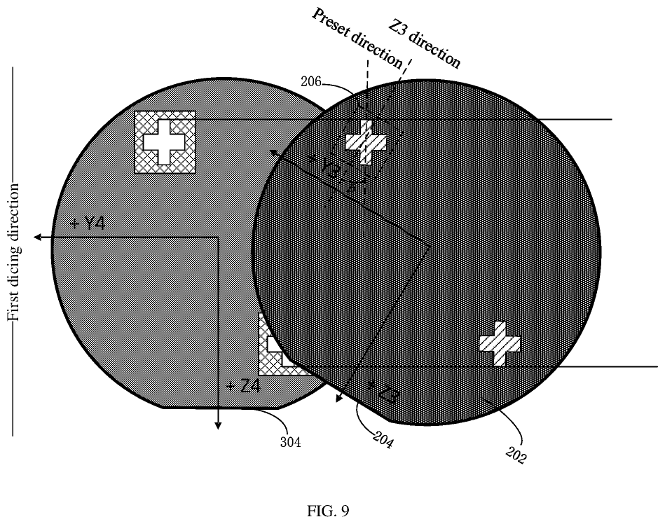

Referring to FIG. 7, it is a top view of the piezoelectric wafer according to another embodiment. Referring to FIG. 8, it is a top view of the carrier wafer according to another embodiment. Referring to FIG. 9, it is a top view of aligning a first marking pattern on the piezoelectric wafer shown in FIG. 7 and a second marking pattern on the carrier wafer shown in FIG. 8 according to an embodiment.

As shown in FIG. 7, FIG. 8, and FIG. 9, it is assumed that there are the crystal orientation+Y3 and crystal orientation+Z3 on the wafer plane of the piezoelectric wafer 202, and there are crystal orientation+Y4 and the crystal orientation+Z4 on the wafer plane of the carrier wafer 302. The crystal orientation+Z3 is used as the crystal axis direction of the piezoelectric wafer 202, and the crystal orientation+Z4 is used as the crystal axis direction of the carrier wafer 302. The first preset angle β is greater than 0 degrees and less than 90 degrees. The first dicing direction is selected as the dicing direction. The second preset angle is 0 degrees. The primary positioning edge 204 of the piezoelectric wafer 202 is perpendicular to the crystal orientation+Z3, and the primary positioning edge 304 of the carrier wafer 302 is perpendicular to the first dicing direction (the crystal orientation+Z4). The method of preparing piezoelectric transducer includes: a first step, the first marking pattern 206 parallel to the preset direction is formed on the piezoelectric wafer 202 (for example, the first marking pattern 206 is a cross-shaped protrusion), and the second marking pattern 306 parallel to the first dicing direction is formed on the carrier wafer 302 (for example, the second marking pattern 306 is a cross-shaped groove); a second step, the first marking pattern 206 and the second marking pattern 306 are aligned, and then the bonding process is performed, and the piezoelectric wafer and the carrier wafer are bonded together to obtain the process wafer. At this time, the preset direction of the piezoelectric transducer is parallel to the first dicing direction of the carrier wafer, and the angle β is formed between the primary positioning edge of the piezoelectric wafer and the primary positioning edge of the carrier wafer.

It should be understood that although the various steps in the flowchart of FIG. 1 are displayed sequentially as indicated by the arrows, these steps are not necessarily executed sequentially in the order indicated by the arrows. Unless otherwise specified herein, there is no strict order restriction on the execution of these steps, and these steps may be executed in other orders. Moreover, at least some of the steps in FIG. 1 may include multiple steps or stages, these steps or stages are not necessarily executed at the same moment, but may be executed at different moments. The execution order of these steps or stages is not necessarily performed sequentially, but may be performed alternately or alternately with other steps or at least a part of steps or stages in other steps.

In the description of this specification, descriptions referring to the terms “some embodiments”, “other embodiments”, “desirable embodiments” and the like mean that a specific feature, structure, material, or characteristic described in connection with the embodiments or examples is included in at least one embodiment or example of the present disclosure. In this specification, schematic descriptions of the above terms do not necessarily refer to the same embodiment or example.

The above-mentioned embodiments do not constitute a limitation on the protection scope of the technical solution. Any modifications, equivalent replacements and improvements made within the spirit and principles of the above-mentioned embodiments shall be included within the protection scope of this technical solution.

The foregoing descriptions are merely specific embodiments of the present disclosure, but are not intended to limit the protection scope of the present disclosure. Any variation or replacement readily figured out by a person skilled in the art within the technical scope disclosed in the present disclosure shall all fall within the protection scope of the present disclosure.

1. A method of preparing a piezoelectric transducer, the method comprising:
forming a first marker parallel to or perpendicular to a preset direction of the piezoelectric transducer on a piezoelectric wafer;
forming a second marker parallel to or perpendicular to a dicing direction of a carrier wafer on the carrier wafer, the second marker and the first marker having the same shape; and
aligning the first marker and the second mark, bonding the piezoelectric wafer and the carrier wafer to form a process wafer, wherein the process wafer comprises a first surface of the piezoelectric wafer configured to form the piezoelectric transducer.

2. The method of claim 1, wherein the first marker comprises a first primary positioning edge of the piezoelectric wafer, the second marker comprises a second primary positioning edge of the carrier wafer, the step of forming the first marker parallel to or perpendicular to the preset direction of the piezoelectric transducer on the piezoelectric wafer comprises:
grinding or cutting the piezoelectric wafer along a first direction to form the first primary positioning edge, the first direction being parallel or perpendicular to the preset direction;
the step of forming the second marker parallel to or perpendicular to the dicing direction of the carrier wafer on the carrier wafer comprises:
grinding or cutting the carrier wafer along a second direction to form the second primary positioning edge, the second direction being parallel or perpendicular to the dicing direction.

3. The method of claim 2, wherein a first preset angle is formed between the preset direction and a crystal axis direction of the piezoelectric wafer, and a second preset angle is formed between the dicing direction and a crystal axis direction of the carrier wafer.

4. The method of claim 3, wherein the first preset angle is an angle by which the preset direction rotates counterclockwise to the crystal axis direction of the piezoelectric wafer, and the second preset angle is the angle by which the dicing direction rotates counterclockwise to the crystal axis direction of the carrier wafer.

5. The method of claim 3, wherein the first preset angle is the angle by which the preset direction rotates clockwise to the crystal axis direction of the piezoelectric wafer, and the second preset angle is the angle by which the dicing direction rotates clockwise to the crystal axis direction of the carrier wafer.

6. The method of claim 3, wherein the first preset angle comprises 0 degrees and 90 degrees, and/or the second preset angle comprises 0 degrees and 90 degrees.

7. The method of claim 3, wherein the piezoelectric wafer further comprises a first secondary positioning edge perpendicular to the first primary positioning edge, and the carrier wafer further comprises a second secondary positioning edge perpendicular to the second primary positioning edge.

8. The method of claim 1, wherein the first marker comprises a first marking pattern provided on the piezoelectric wafer, and the second marker comprises a second marking pattern provided on the carrier wafer;
the step of forming the first marker parallel to or perpendicular to the preset direction of the piezoelectric transducer on the piezoelectric wafer comprises:
forming a first marking pattern on the piezoelectric wafer by a photolithography and etching process, a direction of the first marking pattern being parallel or perpendicular to the preset direction;
the step of forming the second marker parallel to or perpendicular to the dicing direction of the carrier wafer on the carrier wafer comprises:
forming a second marking pattern on the carrier wafer by a photolithography and etching process, and a direction of the second marking pattern being parallel to or perpendicular to the dicing direction.

9. The method of claim 8, wherein the step of forming the first marking pattern on the piezoelectric wafer by the photolithography and etching process comprises:
forming a first marking film layer on the piezoelectric wafer; and
performing the photolithography and etching process to the first marking film layer, and obtaining the first marking pattern;
the step of forming the second marking pattern on the carrier wafer by the photolithography and etching process comprises:
forming a second marking film layer on the carrier wafer; and
performing the photolithography and etching process to the second marking film layer, and obtaining the second marking pattern;
wherein the first marking film layer and the second marking film layer comprise at least a silicon dioxide film layer.

10. The method of claim 9, wherein the first marking pattern is formed by the first marking film layer, and the second marking pattern is a groove provided in the second marking film layer;
or, the first marking pattern is a groove provided in the first marking film layer, and the second marking pattern is formed by the second marking film layer.
